(19) United States
(12) Patent Application Publication
(10) Pub. No.: US 2024/0154036 A1
(43) Pub. Date: May 9, 2024

(54) STACK OF MONOCRYSTALLINE LAYERS FOR PRODUCING MICROELECTRONIC DEVICES WITH 3D ARCHITECTURE

(71) Applicant: COMMISSARIAT À L'ÉNERGIE ATOMIQUE ET AUX ÉNERGIES ALTERNATIVES, Paris (FR)

(72) Inventors: Sylvain Barraud, Grenoble (FR); Shay Reboh, Grenoble (FR)

(21) Appl. No.: 18/502,862

(22) Filed: Nov. 6, 2023

(30) Foreign Application Priority Data
Nov. 8, 2022 (FR) 2211627

(51) Int. Cl. H01L 29/78; H01L 21/8238; H01L 27/092; H01L 29/06; H01L 29/167; H01L 29/423; H01L 29/66; H01L 29/775; H01L 29/786

(52) U.S. Cl. CPC H01L 29/7848; H01L 21/823807; H01L 21/82385; H01L 27/092; H01L 29/0673; H01L 29/167; H01L 29/42392; H01L 29/66439; H01L 29/775; H01L 29/78696

(57) ABSTRACT

Stack of layers of monocrystalline materials suitable for producing microelectronic devices with 3D architecture comprising transistors, including several first layers of monocrystalline material, several second layers of monocrystalline material different from that of the first layers, and at least one third layer of monocrystalline material different from those of the first and second layers, wherein: a first of the monocrystalline materials of the first, second and third layers corresponds to intrinsic silicon; a second of the monocrystalline materials of the first, second and third layers corresponds to intrinsic SiGe; a third of the monocrystalline materials of the first, second and third layers corresponds to p-doped silicon or p-doped SiGe.

### CROSS-REFERENCE TO RELATED APPLICATIONS

This application claims priority from French Patent Application No. 2211627 filed on Nov. 8, 2022. The content of this application is incorporated herein by reference in its entirety.

### TECHNICAL FIELD

The invention relates to the field of microelectronic devices with 3D architecture comprising transistors, produced in particular from multilayer stacks of monocrystalline materials. The invention relates in particular to producing transistors using advanced MOS GAA (Gate-All-Around) technology of the NanoSheet, ForkSheet or CFET (Complementary Field-Effect Transistors) type, or producing memory devices with 3D architecture including access transistors using advanced MOS GAA technology and for example of the 1T1R type (each memory point being formed by a resistive element coupled to an access transistor) or 1T1C type (each memory point being formed by a capacitive element coupled to an access transistor).

### PRIOR ART

The latest CMOS technologies use (and will use) an alternating arrangement of layers of two semiconductor materials that can be selectively removed from each other. This provides the conditions for obtaining so-called “suspended” layers and creating a GAA transistor. The layers used are generally made of Si, Ge, SiGe or GeSn, but the most widespread technology is based on alternating layers of Si and SiGe.

GAA transistor technology based on alternating layers of Si and SiGe uses SiGe with a concentration of Ge comprised between 25 and 35% and thicknesses typically less than 15 nm for each layer of Si and SiGe. In terms of design, one aspect that limits the total number of alternating layers that can be achieved is the mechanical stability of the structure. In the case of Si/SiGe growth on an Si substrate, the SiGe layers are under compressive stress. The layers can retain this stress up to a certain thickness, known as the critical thickness (see for example the document by J. M. Hartmann et al., “Critical thickness for plastic relaxation of SiG on Si(001) revisited”, Journal of applied Physics, vol. 110, 083529 (2011)). At greater thicknesses, the SiGe layer will release some of this stress by emitting dislocations, which is detrimental to the performance/functionality of the device. The same applies to the multilayer stack. As a rough guide, the average Ge concentration in the stack is used to define the critical thickness of the stack. It is therefore clear that using a higher Ge concentration for the layers of the stack limits the total SiGe thickness in the stack. It is therefore necessary to reach a compromise between the number of layers, etch selectivity and mechanical stability.

For certain applications, a third layer of third etch selectivity can be added, for example to isolate the transistor from the substrate or to isolate two channel levels or two superimposed transistors, which can be, for example, complementary transistors (nMOS and pMOS). When this third layer is made of SiGe alloys, it has to have a Ge concentration significantly higher than the Ge concentration in the other SiGe, i.e. of at least 50% to ensure sufficient etch selectivity. The article by J. M. Hartmann et al., “Critical thickness for plastic relaxation of SiG on Si(001) revisited”, Journal of applied Physics, vol. 110, 083529 (2011), shows that the critical thickness is not a linear characteristic relative to the Ge concentration, but rather it decreases sharply with increasing Ge concentration. This brings us to a critical point in terms of design, concerning the mechanical stability of the structure, which could ultimately prove unacceptable.

This limit in the total thickness of the stack is therefore reflected in a limit in the total number of layers in the stack. For example, a three-layer stack comprising alternating layers of silicon, Si_{0.75}Ge_{0.25} and Si_{0.5}Ge_{0.5}, with thicknesses comprised between 12 nm and 13 nm, has a critical thickness comprised between 100 nm and 150 nm. In this case, the maximum number of superimposed layers used to form transistor channels is 3. A high concentration of germanium in such a stack therefore limits the memory capacity that can be achieved per unit area when this stack is used to produce a memory device with 3D architecture, or limits the current density that can be obtained when this stack is used to produce transistors with 3D architecture.

Furthermore, the etch selectivity between the Si_{0.8}Ge_{0.2} or Si_{0.75}Ge_{0.25} layers and the Si_{0.5}Ge_{0.5} layers is not sufficient to avoid consuming one of these layers when etching the other.

### DESCRIPTION OF THE INVENTION

One aim of the present invention is to propose a stack of layers suitable for producing microelectronic devices with 3D architecture comprising transistors, at least partly solving the problem of etch selectivity explained above and being able to have a significant thickness (for example greater than 100 nm or 150 nm) whilst minimizing or eliminating the generation of dislocations by plastic relaxation within the stack in order to improve the memory density (per unit area) or the number of active layers (transistor channels) that can be achieved by the devices produced from such a stack.

For this, the invention proposes a stack of layers suitable for producing microelectronic devices with 3D architecture comprising transistors, including several first layers of unintentionally doped silicon, several second layers of unintentionally doped SiGe, and at least one third layer of P-doped silicon or of P-doped SiGe, such that the first, second and third layers are stacked one above the other.

Compared with the three-layer stacks used in the prior art, it is proposed to replace the layer or layers of SiGe with the greatest Ge concentration with at least one layer of P-doped silicon or P-doped SiGe and, for example, with a low Ge concentration. This stack thus does not have the disadvantages associated with the presence of an SiGe layer with a high Ge concentration, which ultimately improves the memory density (per unit area) or the number of active layers (transistor channels) that can be achieved by the devices produced from such a stack whilst minimizing or eliminating the generation of dislocations by plastic relaxation when the critical thickness within the stack is exceeded.

Moreover, the layer or layers of P-doped silicon or P-doped SiGe can have a greater thickness than the layer or layers of SiGe with a high Ge concentration used in the prior art as their critical thickness before the appearance of dislocations is greater. For example, when this layer or these layers of P-doped silicon or P-doped SiGe are intended to be etched and then replaced by one or more dielectric insulating materials, this makes it possible to form better insulation between stacked structures formed in the stack by producing a thicker insulating structure and/or one comprising an insulating material of low permittivity.

Finally, the etch selectivity obtained between the P-doped silicon, or the P-doped SiGe, and the unintentionally doped silicon and the unintentionally doped SiGe is greater than that obtained in the three-layer stacks in the prior art, which prevents excessive consumption of the materials of the stack during the selective etching of these materials.

Advantageously, said at least one third layer is made of a semiconductor material suitable for being selectively etched with respect to the respective semiconductor materials of the first and second semiconductor layers.

Advantageously, in this stack, said at least one third layer has a so-called “lower” side arranged on and in contact with a given semiconductor layer among said first or second layers or is arranged on and in contact with a semiconductor layer of a substrate. Said at least one third layer can also have a so-called “upper” side opposite said lower side and arranged below and in contact with another semiconductor layer among said first or second layers. Said other semiconductor layer is typically distinct from said given semiconductor layer such that if the third semiconductor layer is in contact with a first layer on one side, upper or lower, it is in contact with a second layer on the opposite side, upper or lower.

According to one possible embodiment, the stack can be entirely made up of three different semiconductor materials.

According to one possible embodiment, the stack can be entirely made up of said first layers of unintentionally doped silicon, said second layers of unintentionally doped SiGe, and said at least one third layer of P-doped silicon or P-doped SiGe.

In the stack proposed, the layers can be stacked such that each first layer is arranged between, and in contact with, two second layers or two third layers, and/or such that each second layer is arranged between, and in contact with, two first layers or two third layers. This characteristic may not apply to some of the first or second layers, such as those at the top of the stack and/or those at the bottom of the stack.

In general, the semiconductors of the first, second and third layers can be monocrystalline, which is advantageous in particular for the semiconductor intended to form transistor channels. Alternatively, it is possible that the semiconductors of the first, second and third layers are polycrystalline.

Silicon or SiGe can be P-doped with boron atoms, for example.

The silicon or SiGe of the third layer can have a concentration of P-type dopants greater than or equal to 5·10¹⁹ at/cm³, and advantageously greater than or equal to 1·10²⁰ at/cm³.

The unintentionally doped SiGe can have a germanium concentration greater than or equal to 10%, or greater than or equal to 20%, and less than 50%.

The number of first or second layers of the stack can be comprised between 4 and 300.

In a first embodiment, each of the first and second layers can be arranged between two third layers and be in contact with these two third layers. A stack according to this first embodiment can advantageously be used to produce memory devices with 3D architecture including access transistors using advanced MOS technology.

In one variant of this first embodiment, the stack can also include several other third layers of P-doped silicon or P-doped SiGe, and each of the first and third layers can be arranged between two of the second layers and be in contact with these two second layers.

In a second embodiment, the stack can comprise at least:
a first sub-stack formed by alternating first and second layers and such that each first layer of the first sub-stack is arranged between two second layers of the first sub-stack or that each second layer of the first sub-stack is arranged between two first layers of the first sub-stack;
a second sub-stack formed by alternating first and second layers and such that each first layer of the second sub-stack is arranged between two second layers of the second sub-stack or that each second layer of the second sub-stack is arranged between two first layers of the second sub-stack;
and the third layer can be arranged between the first and second sub-stacks. A stack according to this second embodiment can advantageously be used to produce CFET transistors, i.e. n-type and p-type transistors stacked one on top of the other and the channels of which are formed by a superposition of nanowires and nanosheets.

In this second embodiment, the stack can also include several other third layers of p-doped silicon or p-doped SiGe between which the first and second sub-stacks are arranged.

In a third embodiment, the first and second layers can be arranged one above the other in alternating rows, and the third layer can be arranged under an assembly formed by the first and second layers. A stack according to this third embodiment can advantageously be used to produce CMOS GAA transistors.

The invention also relates to a first method for producing microelectronic devices with 3D architecture comprising transistors, including the implementation of the following steps:
a) producing a stack according to the first embodiment on a substrate and wherein each of the first and second layers is arranged between two third layers and is in contact with these two third layers;
b) etching trenches and/or cavities through at least part of the thickness of the stack, such that remaining portions of the first, second and third layers form nanowires or nanosheets;
c) selectively etching some of the remaining portions of the first layers such that remaining parts of the first layers are designed to form transistor channels;
d) depositing at least one first dielectric material in first spaces formed by selectively etching some of the remaining portions of the first layers, next to the transistor channels;
e) selectively etching at least some of the remaining portions of the second layers;
d) depositing at least one second dielectric material in second spaces formed by selectively etching at least some of the remaining portions of the second layers, between the remaining portions of the third layers;
g) selectively etching remaining portions of the third layers;
h) depositing at least one gate dielectric and at least one gate conductor material in third spaces formed by selectively etching remaining portions of the third layers, forming a gate at least above and below each of the transistor channels.

Alternatively, the invention also proposes a method for producing microelectronic devices with 3D architecture comprising transistors, including the implementation of the following steps:
a) producing a stack according to the first embodiment on a substrate and wherein each of the first and second layers is arranged between two third layers and is in contact with these two third layers;
b) etching trenches and/or cavities through at least part of the thickness of the stack, such that remaining portions of the first, second and third layers form nanowires or nanosheets;
c) selectively etching some of the remaining portions of the second layers such that remaining parts of the second layers are designed to form transistor channels;
d) depositing at least one first dielectric material in first spaces formed by selectively etching some of the remaining portions of the second layers, next to the transistor channels;
e) selectively etching at least some of the remaining portions of the first layers;
d) depositing at least one second dielectric material in second spaces formed by selectively etching at least some of the remaining portions of the first layers, between the remaining portions of the third layers;
g) selectively etching remaining portions of the third layers;
h) depositing at least one gate dielectric and at least one gate conductor material in third spaces formed by selectively etching remaining portions of the third layers, forming a gate at least above and below each of the transistor channels.

The two methods above can advantageously be implemented to produce memory devices with 3D architecture including access transistors using advanced MOS technology.

According to another variant of this first embodiment, the invention proposes a method for producing microelectronic devices with 3D architecture comprising transistors, including the implementation of the following steps:
a) producing a stack according to the first embodiment on a substrate, the stack also including several other third layers of P-doped silicon or P-doped SiGe, and wherein each of the first and third layers is arranged between two second layers and is in contact with these two second layers;
b) etching trenches and/or cavities through at least part of the thickness of the stack, such that remaining portions of the first, second and third layers form nanowires or nanosheets;
c) selectively etching some of the remaining portions of the first layers such that remaining parts of the first layers are designed to form transistor channels;
d) depositing at least one first dielectric material in first spaces formed by selectively etching some of the remaining portions of the first layers, next to the transistor channels;
e) selectively etching at least some of the remaining portions of the third layers;
d) depositing at least one second dielectric material in second spaces formed by selectively etching at least some of the remaining portions of the third layers, between the remaining portions of the second layers;
g) selectively etching remaining portions of the second layers;
h) depositing at least one gate dielectric and at least one gate conductor material in third spaces formed by selectively etching remaining portions of the second layers, forming a gate at least above and below each of the transistor channels.

Alternatively, steps e) and f) can be implemented between steps b) and c).

The invention also relates to a second method for producing microelectronic devices with 3D architecture comprising transistors, including the implementation of the following steps:
a) producing a stack according to the second embodiment on a substrate;
b) etching trenches and/or cavities through at least part of the thickness of the stack, such that remaining portions of the first and second layers of the first and second sub-stacks and remaining portions of the third layer or third layers form nanowires or nanosheets;
e) selectively etching at least some of the remaining portions of the third layer or third layers;
d) depositing at least one first dielectric material in first spaces formed by selectively etching at least some of the remaining portions of the third layer;
e) selectively etching at least some of the remaining portions of the second layers of the first sub-stack when, in the first sub-stack, each first layer is arranged between two second layers, or selectively etching at least some of the remaining portions of the first layers of the first sub-stack when, in the first sub-stack, each second layer is arranged between two first layers;
f) depositing at least one gate dielectric and at least one gate conductor material in second spaces formed by the selective etching in step e), forming a gate at least above and below each of the remaining portions of the first or second layers of the first sub-stack.

Such a method can advantageously be implemented to produce CFET transistors.

This second method may be such that:
when each first layer is arranged between two second layers in the first and second sub-stacks, step e) also includes selectively etching at least some of the remaining portions of the second layers of the second sub-stack, and step f) also includes depositing the gate dielectric and the gate conductor material in third spaces formed by selectively etching at least some of the remaining portions of the second layers of the second sub-stack, forming a gate at least above and below each of the remaining portions of the first layers of the second sub-stack, or
when each second layer is arranged between two first layers in the first and second sub-stacks, step e) also includes selectively etching at least some of the remaining portions of the first layers of the second sub-stack, and step f) also includes depositing the gate dielectric and the gate conductor material in third spaces formed by selectively etching at least some of the remaining portions of the first layers of the second sub-stack, forming a gate at least above and below each of the remaining portions of the second layers of the second sub-stack, or
when each first layer is arranged between two second layers in the first sub-stack and each second layer is arranged between two first layers in the second sub-stack, the method also includes, after step f), a step g) of selectively etching at least some of the remaining portions of the first layers of the second sub-stack, then a step h) of depositing at least one gate dielectric and at least one gate conductor material in third spaces formed by etching at least some of the remaining portions of the first layers of the second sub-stack, forming a gate at least above and below each of the remaining portions of the second layers of the first sub-stack, or
when each second layer is arranged between two first layers in the first sub-stack and each first layer is arranged between two second layers in the second sub-stack, the method also includes, after step f), a step g) of selectively etching at least some of the remaining portions of the second layers of the second sub-stack, then a step h) of depositing at least one gate dielectric and at least one gate conductor material in third spaces formed by selectively etching at least some of the remaining portions of the second layers of the second sub-stack, forming a gate at least above and below each of the remaining portions of the first layers of the first sub-stack.

The invention also relates to a method for producing microelectronic devices with 3D architecture comprising transistors, including the implementation of the following steps:
a) producing a stack according to the third embodiment on a substrate;
b) etching trenches and/or cavities through at least part of the thickness of the stack, such that remaining portions of the first and second layers of the first and second sub-stacks and remaining portions of the third layer form nanowires or nanosheets;
e) selectively etching at least some of the remaining portions of the third layer;
d) depositing at least one first dielectric material in first spaces formed under the remaining portions of the first and second layers, providing electrical insulation between the remaining portions of the first and second layers and the substrate;
e) selectively etching at least some of the remaining portions of the first layers or second layers;
f) depositing at least one gate dielectric and at least one gate conductor material in second spaces formed by etching at least some of the remaining portions of the first layers or second layers, forming a gate at least above and below each of the remaining portions of the first layers or second layers.

Such a method can advantageously be implemented to produce CMOS GAA transistors.

Throughout the document, the term “on” is used irrespective of the orientation in space of the element to which this term relates. For example, in the feature “on a side of the first substrate”, this side of the first substrate does not necessarily face upwards but may correspond to a side facing in any direction. Furthermore, the arrangement of a first element on a second element should be understood as possibly corresponding to the arrangement of the first element directly against the second element, without any intermediate element between the first and second elements, or as possibly corresponding to the arrangement of the first element on the second element with one or more intermediate elements arranged between the first and second elements.

In the methods described above and in the particular embodiments described below, the steps described are not necessarily carried out directly one after the other because intermediate steps may be carried out between two steps of these methods.

### BRIEF DESCRIPTION OF THE DRAWINGS

The present invention will be better understood upon reading the description of exemplary embodiments given purely by way of illustration and in no way restrictively, with reference to the appended drawings wherein:

FIG. 1 shows a stack of layers of monocrystalline materials suitable for producing microelectronic devices with 3D architecture comprising transistors, object of the present invention, according to a first embodiment.

FIG. 2 shows the steps of a method for producing microelectronic devices with 3D architecture comprising transistors, object of the present invention, implemented from a stack according to the first embodiment.

FIG. 3 shows the steps of an alternative to the method described with reference to FIG. 2.

FIG. 4 shows a stack of layers of monocrystalline materials suitable for producing microelectronic devices with 3D architecture comprising CFET transistors, object of the present invention, according to a second embodiment.

FIGS. 5 and 6 show the steps of a method for producing microelectronic devices with 3D architecture comprising CFET transistors, object of the present invention, implemented from a stack according to the second embodiment.

FIG. 7 shows a stack of layers of monocrystalline materials suitable for producing microelectronic devices with 3D architecture comprising CFET transistors, object of the present invention, according to an alternative to the second embodiment.

FIGS. 8 and 9 show the steps of a method for producing microelectronic devices with 3D architecture comprising CFET transistors, object of the present invention, implemented from a stack according to the alternative to the second embodiment.

FIG. 10 shows a stack of layers of monocrystalline materials suitable for producing microelectronic devices with 3D architecture comprising GAA transistors, object of the present invention, according to a third embodiment.

FIGS. 11 and 12 show the steps of a method for producing microelectronic devices with 3D architecture comprising GAA transistors, object of the present invention, implemented from a stack according to the third embodiment.

Identical, similar or equivalent parts of the different figures described hereinafter bear the same reference numerals so as to facilitate switching from one figure to another.

The different parts shown in the figures are not necessarily plotted according to a uniform scale, to make the figures more readable.

The various possibilities (alternatives and embodiments) must be understood as not being mutually exclusive and can be combined with one another.

### DETAILED DISCLOSURE OF PARTICULAR EMBODIMENTS

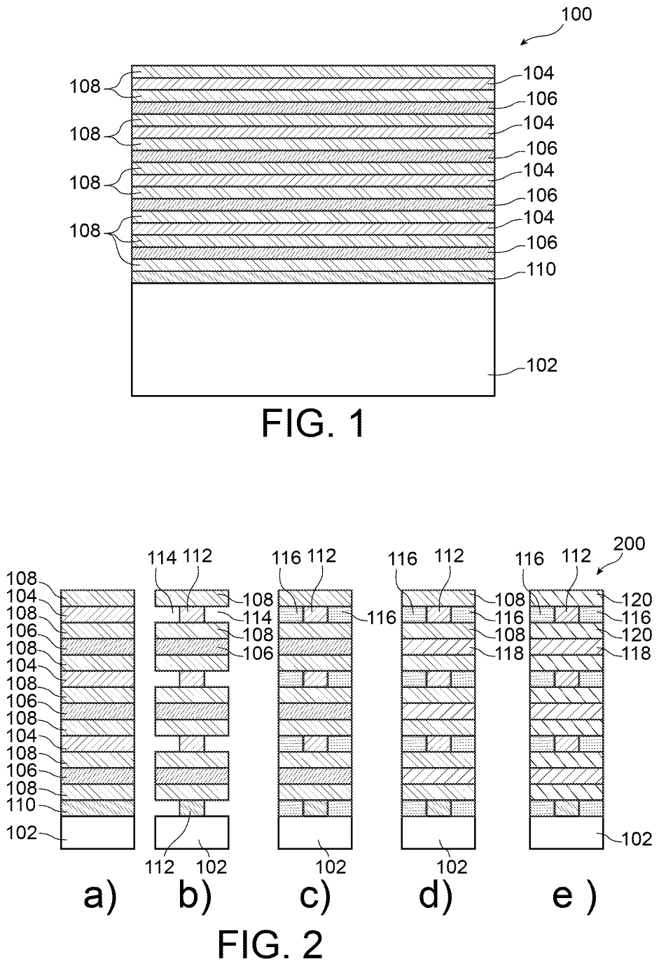

A stack 100 of layers of monocrystalline materials suitable for producing microelectronic devices with 3D architecture comprising transistors, according to a first embodiment, is described below with reference to FIG. 1.

The stack 100 is arranged on a substrate 102 corresponding, for example, to a bulk substrate, of semiconductor material, for example silicon. Advantageously, the substrate 102 can correspond to a semiconductor-on-insulator substrate, for example SOI (“silicon on insulator”).

The stack 100 includes several first layers 104 of unintentionally doped silicon, several second layers 106 of unintentionally doped SiGe, and at least one third layer 108 (several third layers 108 in the example of FIG. 1) of P-doped silicon or P-doped SiGe.

In the first embodiment, each of the first and second layers 104, 106 is arranged between two third layers 108 and is in contact with these two third layers 108. In the example of FIG. 1, the stack 100 includes four first layers 104, four second layers 106 and nine third layers 108.

The stack 100 shown in FIG. 1 also includes a layer 110 that is similar to one of the first layers 104 and arranged between the substrate 102 and the stack 100. In the exemplary embodiment described, unlike the first layers 104, the layer 110 is not arranged between two third layers 108. Alternatively, it is possible to have the layer 110 arranged between two third layers 108. In the case of an SOI-type substrate 102, the layer 110 can correspond to the silicon surface layer of this substrate 102, a buried dielectric layer or BOX (buried oxide) layer being present in this case under the layer 110 (such a BOX is not shown in FIG. 1).

In one variant, it is possible that the stack 100 includes, at its top, an unintentionally doped SiGe layer that is thicker than the layers 106.

Advantageously, the total number of first layers 104 of the stack 100 is comprised between 4 and 300.

In the particular exemplary embodiment in FIG. 1, a third layer 103 has a lower side arranged on and in contact with a silicon surface layer 110 of this substrate 102 and an upper side opposite the upper side which is arranged under and in contact with a layer 106.

Other third layers 103 have a lower side which is arranged on and in contact with a first layer 104 and an upper side which is arranged on and in contact with a second layer 106, or a lower side which is arranged on and in contact with a second layer 106 and an upper side which is arranged on and in contact with a first layer 104.

In the exemplary embodiment shown in FIG. 1, the third layers 108 have P-doped silicon. In addition, the silicon of the third layers has a concentration of P-type dopants, corresponding advantageously to boron atoms, greater than or equal to 5·10¹⁹ at/cm³, or greater than or equal to 10²⁰ at/cm³. In addition, in the exemplary embodiment described here, the unintentionally doped SiGe has a germanium concentration greater than or equal to 10%, or greater than or equal to 20%, and for example equal to 30%. Furthermore, in this exemplary embodiment, the unintentionally doped SiGe also has a germanium concentration of less than 50%.

The thickness of each of the layers 104, 106, 108 and 110 is, for example, comprised between 5 nm and 30 nm.

A method for producing microelectronic devices with 3D architecture 200 comprising transistors, implemented from the stack 100 according to the first embodiment, is described below with reference to FIG. 2. In order to simplify the description of this method, only some of the layers of the stack 100 are shown in FIG. 2. In addition, various elements of the transistors produced such as the dummy gate, the lateral spacers, the source and drain regions, etc., as well as other elements of the device 200, are not shown in FIG. 2 in order to facilitate the understanding of the invention.

A first step of the method consists of producing the stack 100 on the substrate 102. The various layers 104, 106, 108, 110 of the stack 100 can be produced by epitaxy on the upper side of the substrate 102. The stack 100 obtained following these epitaxy steps corresponds to the one shown in FIG. 1.

Trenches and/or cavities (for example contact holes) are then made through at least part of the thickness of the stack 100 (all the thickness of the stack 100 in the example in FIG. 2) such that remaining portions of the different layers 104, 106 and 108 of the stack 100 form nanowires or nanosheets. In the exemplary embodiment described here, this etching step is also carried out through the layer 110. This etching step is carried out by creating an etching mask (not shown) at the top of the stack 100, defining the pattern to be etched through the stack 100. This etching is, for example, dry plasma etching using C₄F₆/O₂ and/or HBr/O₂. In the case of an SOI-type substrate 102, this etching can be stopped on the buried dielectric layer of the substrate 102. In FIG. 2, view a, only one of the remaining portions of each of the layers 104, 106, 108, 110 of the stack 100 is shown.

Although this is not shown in FIG. 2, microelectronic devices with 3D architecture 200 can continue to be produced by forming, for example, a dummy gate on and against side walls of the remaining portions of the stack 100. Lateral spacers, which are likewise not shown in FIG. 2, can then be produced next to the dummy gate, also on and against the side walls of the remaining portions of the stack 100.

Selective etching of some of the remaining portions of the first layers 104, and also of the layer 110 in the exemplary embodiment described here, is then carried out so as to form transistor channels which will be produced from the stack 100. This etching of the material of the first layers 104 and of the layer 110, i.e. of unintentionally doped silicon, is selective with respect to the materials of the other layers 106 and 108 of the stack 100, i.e. selective with respect to the unintentionally doped SiGe of the second layers 106 and the P-doped silicon of the third layers 108. In the exemplary embodiment described here, this etching corresponds to isotropic etching corresponding, for example, to wet etching that can be carried out with an EDP (ethylenediamine pyrocatechol)-, KOH-, NaOH- and LiOH-based solution.

As is shown in FIG. 2, view b, this etching forms the future transistor channels 112 corresponding to the remaining portions of material of the first layers 104, and also of the layer 110 in this example. With the implementation of this etching, first spaces 114 are also formed next to the channels 112, uncovering lateral flanks of the channels 112.

At least one first dielectric material 116 is then deposited in the first spaces 114 (see FIG. 2, view c). Advantageously, this first dielectric material 116 corresponds to an oxide, for example SiO₂. The deposition carried out is, for example, CVD or ALD.

Selective etching of at least some of the remaining portions of the second layers 106, and preferably all the remaining portions of the second layers 106, is then carried out. This etching of the material of the second layers 106, i.e. of unintentionally doped SiGe, is selective with respect to the materials of the other layers 102, 108, 116 and 110 of the stack 100, i.e. selective with respect to the unintentionally doped silicon of the first layers 104 and of the layer 110, the P-doped silicon of the third layers 108, and also with respect to the first dielectric material of the portions 116. In the exemplary embodiment described here, this etching corresponds, for example, to wet etching that can be carried out with an acetic acid-based HF H₂O₂ or HNO₃-based solution combined with oxide etchants (details of implementation given for example in the document “The Effect of Doping on the Digital Etching of Silicon-Selective Silicon-Germanium Using Nitric Acids” de Li et al., Nanomaterials, 2021, 11(5), 1209). With the implementation of this etching, second spaces are formed between the third layers 108.

Although this is not shown in FIG. 2, the mechanical stability of the stack is guaranteed by the presence of materials situated outside the planes shown in FIG. 2.

At least one second dielectric material 118 is then deposited in the second spaces (see FIG. 2, view d). By way of example, this second dielectric material 118 corresponds to nitride, for example SiN. The deposition carried out is, for example, CVD or ALD. The portions of this second dielectric material 118 are intended here to form dielectric isolation portions between the gates of the different levels of the GAA transistors that will be produced.

Selective etching of at least some of the remaining portions of the third layers 108, and preferably all the remaining portions of the third layers 108, is then carried out. This etching of the material of the third layers 108, i.e. of doped silicon in the example described here, is selective with respect to the materials present, i.e. selective with respect to the unintentionally doped silicon of the first layers 104 and of the layer 110, the unintentionally doped SiGe of the second layers 106, and the first and second dielectric materials of the portions 116 and 118. In the exemplary embodiment described here, this etching corresponds, for example, to wet etching that can be carried out with an HNA-based solution, i.e. HF, HNO₃ and propionic acid.

Depositing at least one gate dielectric and at least one gate conductor material in third spaces formed by selectively etching one of the remaining portions of the third layers 108, forming a gate 120 above and below each of the transistor channels 112. The gate dielectric and the gate conductor material correspond, for example, to a superposition of HfO₂, TiN and W. The structure obtained is shown in FIG. 2, view e.

Alternatively, it is possible that the portions 116 are etched before the gate dielectric and the gate conductor material are deposited, and that one or several materials different from that of the portions 116 are deposited in the cavities obtained by this etching.

Other steps, such as producing spacers, source and drain regions, electrical contacts, memory elements when the stack 100 is used to produce 3D memory devices, etc., are also carried out to complete the production of the microelectronic devices with 3D architecture 200.

Alternatively, the stack 100 can be advantageously used to produce a 3D memory device such as that described in the patent application FR 21 05264, which makes it possible, compared to the materials described in the application FR 21 05264, to produce a 3D memory device comprising a larger number of superimposed memory levels, and therefore a larger memory density/unit area.

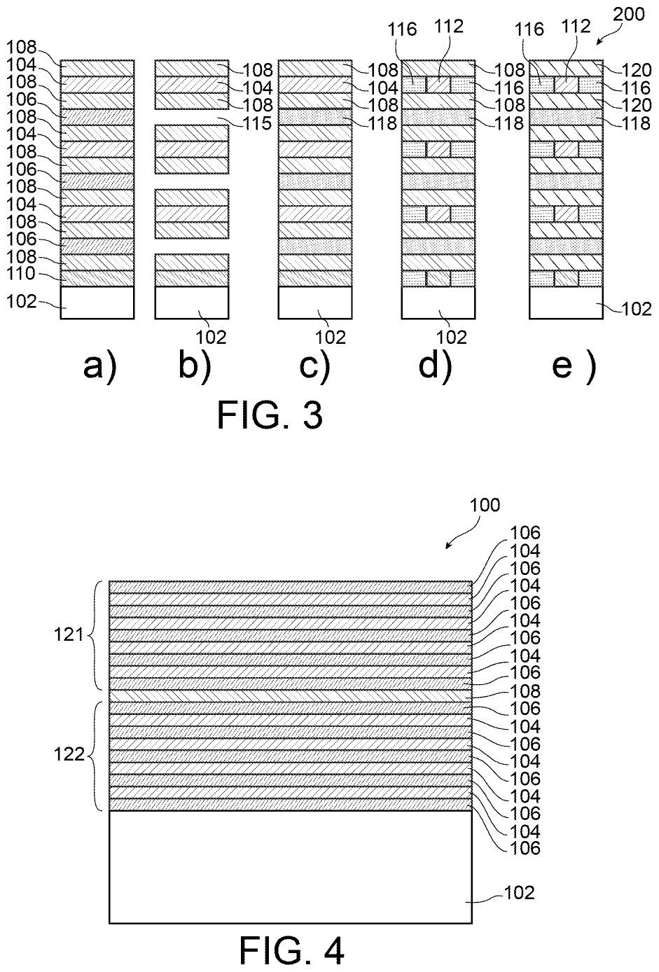

Another method for producing microelectronic devices with 3D architecture 200 comprising transistors, implemented from the stack 100 according to the first embodiment, is described below with reference to FIG. 3. In order to simplify the description of this method, only some of the layers of the stack 100 are shown in FIG. 3.

In this method, the same steps as those of the method described above with reference to FIG. 2 are carried out, but in a different order. Thus, compared to the method described above with reference to FIG. 2, the steps of etching at least some of the remaining portions of the second layers 106 and depositing the second dielectric material 118 are carried out before the steps of etching some of the remaining portions of the first layers 104 and depositing the first dielectric material 116. In FIG. 3, view b, the spaces formed by etching at least some of the remaining portions of the second layers 106 are indicated by reference numeral 115. In this method, it is possible that the second dielectric material 118 corresponds to SiCO or SiN. As with the previous method, after the first and second dielectric materials 116, 118 have been deposited, at least some of the remaining portions of the third layers 108 are etched and the materials forming the gates 120 of the transistors are deposited.

As a variant of the stack 100 described above according to the first embodiment, it is possible that each of the first and third layers 104, 108 is arranged between two second layers 106 and is in contact with these two second layers 106. The two methods described above can be implemented using a stack 100 according to this variant, by adapting in this case the etchants used depending on the materials to be etched.

In the methods described above, the first layers 104 are used to form the transistor channels in the device. Alternatively, it is possible that the second layers 106 are partially etched so that the remaining parts of the portions of the second layers 106 are used to form the transistor channels in these devices.

The stack 100 according to the first embodiment and according to the variant above of the first embodiment is well suited to producing memory devices with 3D architecture 200 and, for example, of 1T1R or 1T1C type.

A stack 100 of layers of monocrystalline materials suitable for producing microelectronic devices with 3D architecture comprising CFET transistors, according to a second embodiment, is described below with reference to FIG. 4.

As with the first embodiment, the stack 100 according to the second embodiment is produced on the substrate 102 and has first layers 104, second layers 106 and at least one third layer 108 (only one in the example in FIG. 4). The materials of these layers 104, 106 and 108 are similar to those described above with reference to the first embodiment.

In this second embodiment, the first and second layers 104 and 106 of the stack 100 are distributed to form several sub-stacks each separated by a third layer 108. In the example in FIG. 4, the stack 100 includes:
a first sub-stack 121 formed by alternating first and second layers 104, 106 such that each first layer 104 of the first sub-stack 121 is arranged between two second layers 106 of the first sub-stack 121;
a second sub-stack 122 formed by alternating first and second layers 104, 106 such that each first layer 104 of the second sub-stack 122 is arranged between two second layers 106 of the second sub-stack 122.

The stack 100 shown in FIG. 4 also has a third layer 108 arranged between the first and second sub-stacks 121, 122.

In the example in FIG. 4, each of the first and second sub-stacks 121, 122 has four first layers 104 and five second layers 106.

The individual characteristics (thickness, doping, etc.) of each of the layers 104, 106, 108 of the stack according to this second embodiment are, for example, the same as those described above for the stack 100 according to the first embodiment.

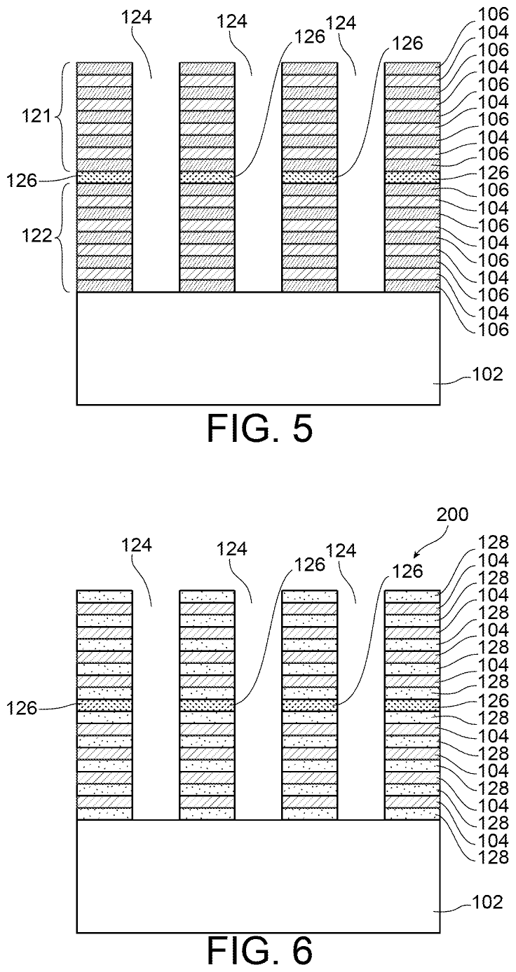

A method for producing microelectronic devices with 3D architecture 200 comprising transistors, implemented from the stack 100 according to the second embodiment, is described below with reference to FIGS. 5 and 6.

The stack 100 as described above with reference to FIG. 4 is first of all produced on the substrate 102. The various layers 104, 106 and 108 of the stack 100 can be produced by epitaxy on the upper side of the substrate 102.

As with the methods described above, trenches and/or cavities are then etched through at least part of the thickness of the stack 100 (through all the thickness of the stack 100 in the exemplary embodiment described here) such that remaining portions of the different layers 104, 106 and 108 of the stack 100 form nanowires or nanosheets. In FIGS. and 6, some of these etched trenches are indicated by the reference numeral 124.

Selective etching of at least some of the remaining portions of the third layer 108, and preferably all the remaining portions of the third layers 108, is then carried out, then at least one first dielectric material 126, for example of SiO₂ or SiN, is deposited in first spaces formed between the sub-stacks 121, 122. This first dielectric material 126 provides electrical insulation between the semiconductor materials of the sub-stacks 121, 122. The structure obtained at this stage of the method is shown in FIG. 5.

Selective etching of at least some of the remaining portions of the second layers 106 of the sub-stacks 121, 122, and preferably all the remaining portions of the second layers 106 of the sub-stacks 121, 122, is carried out subsequently. At least one gate dielectric and at least one gate conductor material are then deposited in second spaces formed by the previous selective etching of the remaining portions of the second layers 106, forming a gate 128 above and below each of the remaining portions of the first layers 104 of the sub-stacks 121, 122. The structure obtained is shown in FIG. 6.

Other steps (not described here), such as producing spacers, source and drain regions, electrical contacts, etc., are also carried out to complete the production of the microelectronic devices with 3D architecture 200. These devices can include CFET-type transistors such that one of the NMOS or PMOS-type transistors includes a channel formed by the remaining portions of the first layers 104 of the first sub-stack 121 and the other of the transistors, respectively PMOS or NMOS-type, includes a channel formed by the remaining portions of the first layers 104 of the second sub-stack 122.

As an alternative to the configuration shown in FIG. 4, it is possible that the stack 100 includes:
a first sub-stack 121 formed by alternating first and second layers 104, 106 such that each second layer 106 of the first sub-stack 121 is arranged between two first layers 104 of the first sub-stack 121;
a second sub-stack 122 formed by alternating first and second layers 104, 106 such that each second layer 106 of the second sub-stack 122 is arranged between two first layers 104 of the second sub-stack 122.

In this case, when producing microelectronic devices with 3D architecture from such a stack, it is the remaining portions of the first layers 104 of the sub-stacks 121, 122 that are selectively etched with respect to the remaining portions of the second layers 106. The gates 128 are then produced above and below each of the remaining portions of the second layers 106 of the sub-stacks 121, 122 that are intended to form the transistor channels.

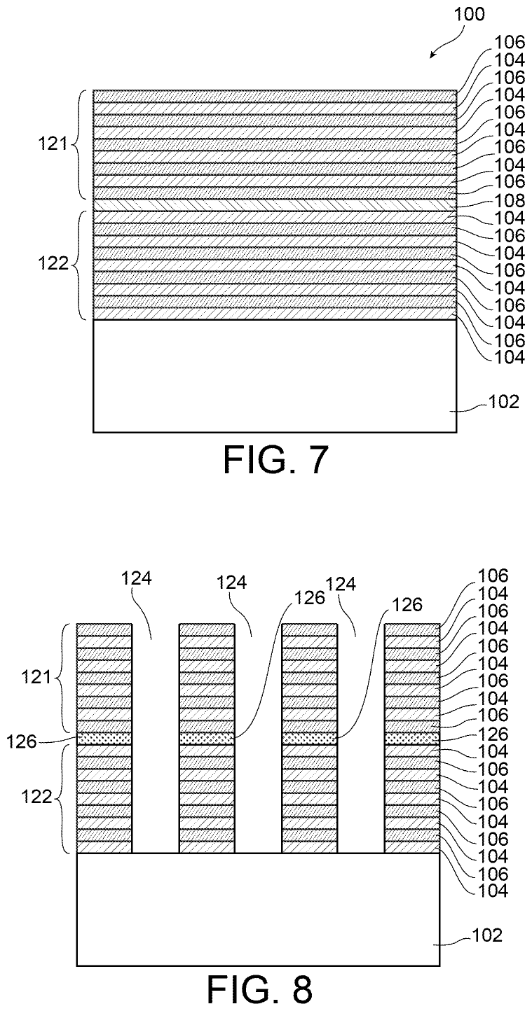

A stack 100 of layers of monocrystalline materials suitable for producing microelectronic devices with 3D architecture comprising GAA transistors, according to a variant of the second embodiment, is described below with reference to FIG. 7.

As with the previous embodiments, the stack 100 according to this variant of the second embodiment is produced on the substrate 102 and has first layers 104, second layers 106 and at least one third layer 108 (only one in the example in FIG. 7). The materials of these layers 104, 106 and 108 are similar to those described above with reference to the first and second embodiments.

As with the second embodiment, the first and second layers 104 and 106 of the stack 100 are distributed to form several sub-stacks each separated by a third layer 108. In the example in FIG. 7, the stack 100 includes:
a first sub-stack 121 formed by alternating first and second layers 104, 106 such that each first layer 104 of the first sub-stack 121 is arranged between two second layers 106 of the first sub-stack 121;
a second sub-stack 122 formed by alternating first and second layers 104, 106 such that each second layer 106 of the second sub-stack 122 is arranged between two first layers 104 of the second sub-stack 122.

The stack 100 shown in FIG. 7 also has a third layer 108 arranged between the first and second sub-stacks 121, 122.

In the example in FIG. 7, the first sub-stack 121 has four first layers 104 and five second layers 106, the second sub-stack 122 has five first layers 104 and four second layers 106.

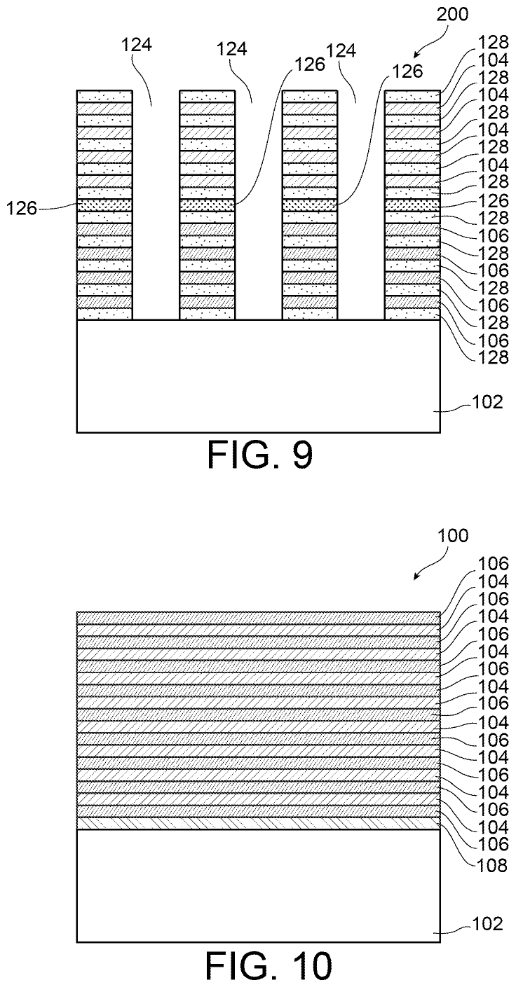

A method for producing microelectronic devices with 3D architecture comprising transistors, implemented from the stack 100 according to this variant of the second embodiment, is described below with reference to FIGS. 8 and 9.

The stack 100 as described above with reference to FIG. 7 is first of all produced on the substrate 102. The various layers 104, 106 and 108 of the stack 100 can be produced by epitaxy on the upper side of the substrate 102.

As with the methods described above, trenches and/or cavities are then made through at least part of the thickness of the stack 100 (through all the thickness of the stack 100 in the example described here) such that remaining portions of the different layers 104, 106 and 108 of the stack 100 form nanowires or nanosheets. In FIGS. 8 and 9, some of these etched trenches are indicated by the reference numeral 124.

Selective etching of at least some of the remaining portions of the third layer 108, and preferably all the remaining portions of the third layers 108, is then carried out, then at least one first dielectric material 126, for example of SiO₂ or SiN, is deposited in first spaces formed between the sub-stacks 121, 122. This first dielectric material 126 is intended to provide electrical insulation between the sub-stacks 121, 122. The structure obtained at this stage of the method is shown in FIG. 8.

Selective etching of at least some of the remaining portions of the second layers 106 of the first sub-stack 121, and preferably all the remaining portions of the second layers 106 of the first sub-stack 121, is carried out subsequently.

Selective etching of at least some of the remaining portions of the first layers 104 of the second sub-stack 122, and preferably all the remaining portions of the second layers 104 of the second sub-stack 122, is carried out subsequently. During these steps, the first sub-stack 121 is protected so as to not damage the materials of the first sub-stack 121 during this selective etching.

At least one gate dielectric and at least one gate conductor material are deposited in second and third spaces formed by selectively etching the remaining portions of the second layers 106 of the first sub-stack 121 and by selectively etching the remaining portions of the first layers 104 of the second sub-stack 122, forming a gate 128 above and below each of the remaining portions of the first layers 104 of the first sub-stack 121 and remaining portions of the second layers 106 of the second sub-stack 122.

Other steps (not described here), such as producing spacers, source and drain regions, electrical contacts, etc., are also carried out to complete the production of the microelectronic devices with 3D architecture 200. These devices can include CFET-type transistors such that NMOS transistors include a channel formed by the remaining portions of the first layers 104 of the first sub-stack 121 and PMOS transistors include a channel formed by the remaining portions of the second layers 106 of the second sub-stack 122.

Alternatively, it is also possible that the PMOS transistors have their channels formed by the remaining portions of the first layers 104 of the first sub-stack 121 and that NMOS transistors have their channels formed by the remaining portions of the second layers 104 of the first sub-stack 121.

As an alternative to the method described above with reference to FIGS. 7 to 9, it is possible to first of all etch the remaining portions of the first layers 104 of the second sub-stack 122, then to etch the remaining portions of the second layers 106 of the first sub-stack 121, and finally to produce the gates 128 in the second sub-stacks 121, 122.

As an alternative to the stack 100 described above with reference to FIG. 7, it is possible to produce this stack 100 such that:
the first sub-stack 121 is formed by alternating first and second layers 104, 106 such that each second layer 106 of the first sub-stack 121 is arranged between two first layers 104 of the first sub-stack 121;
the second sub-stack 122 is formed by alternating first and second layers 104, 106 such that each first layer 104 of the second sub-stack 122 is arranged between two second layers 106 of the second sub-stack 122.

In this case, in the various methods described above that can be applied to such a stack, the selective etching carried out in the first sub-stack 121 corresponds to selective etching of the remaining portions of the first layers 104 of the first sub-stack 121 with respect to the remaining portions of the second layers 106 of the first sub-stack 121, and the selective etching carried out in the second sub-stack 122 corresponds to selective etching of the remaining portions of the second layers 106 of the second sub-stack 122 with respect to the remaining portions of the first layers 104 of the second sub-stack 122.

When the stack 100 has several sub-stacks as described above, it is possible that this stack 100 also includes several other third layers 108 of p-doped silicon or p-doped SiGe between which the sub-stacks 121, 122 are arranged.

When the layers of material of the stack 100 are divided into several sub-stacks as is the case in the examples described above, the total number of layers of material of each of the sub-stacks 121, 122 intended to form transistor channels is advantageously comprised between 3 and 10. Moreover, the number of layers of material in each of the sub-stacks can be the same or different. For example, considering the exemplary embodiments described above with reference to FIGS. 4 and 7, the number of layers of material of the first sub-stack 121 could be different from that of the second sub-stack 122. Finally, the stack 100 can include more than two sub-stacks of layers of monocrystalline materials.

A stack 100 of layers of monocrystalline materials suitable for producing microelectronic devices with 3D architecture comprising GAA transistors, according to a third embodiment, is described below with reference to FIG. 10.

As with the previous embodiments, the stack 100 according to the third embodiment is produced on the substrate 102 and has first layers 104, second layers 106 and at least one third layer 108 (only one in the example in FIG. 10). The materials of these layers 104, 106 and 108 are similar to those described above with reference to the previous embodiments.

In this third embodiment, the first and second layers 104 and 106 of the stack 100 are arranged one above the other in alternating rows. In the example shown in FIG. 10, each first layer 104 is arranged between two second layers 106 and is in contact with these two second layers 106.

The stack 100 shown in FIG. 10 also has a third layer 108 arranged below the first and second layers 104, 106, between the substrate 102 and the assembly of first and second layers 104, 106.

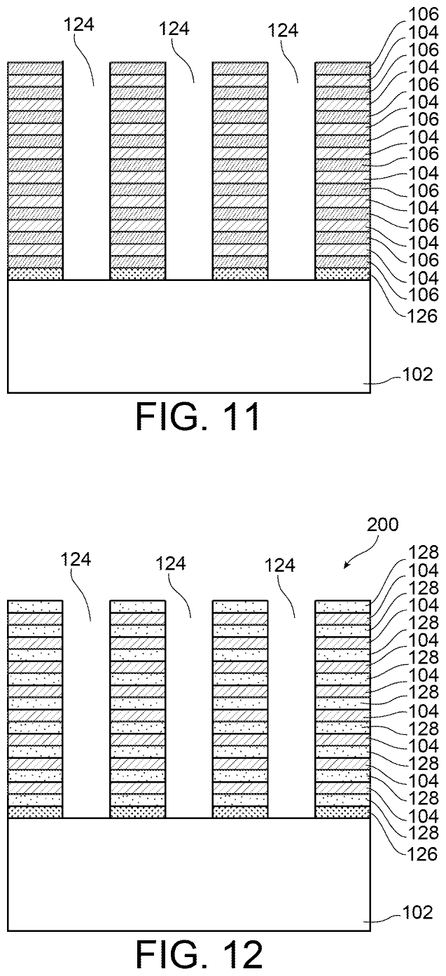

A method for producing microelectronic devices with 3D architecture comprising transistors, implemented from the stack 100 according to the third embodiment, is described below with reference to FIGS. 11 and 12.

The stack 100 as described above with reference to FIG. 10 is first of all produced on the substrate 102. The various layers 104, 106 and 108 of the stack 100 can be produced by epitaxy on the upper side of the substrate 102.

As with the methods described above, trenches and/or cavities are then made through all the thickness of the stack 100 such that remaining portions of the different layers 104, 106 and 108 of the stack 100 form nanowires or nanosheets. In FIGS. 11 and 12, some of these etched trenches are indicated by the reference numeral 124.

Selective etching of at least some of the remaining portions of the third layer 108, and preferably all the remaining portions of the third layer 108, is then carried out. At least one first dielectric material 126, for example SiO₂ or SiN, is deposited conformally, for example by ALD or CVD deposition, and then selectively and isotropically etched so as to retain portions of this first dielectric material only under the remaining portions of the layers 104, 106. This first dielectric material 126 provides electrical insulation between the substrate 102 and the channel closest to the substrate 102. The structure obtained at this stage of the method is shown in FIG. 11.

Selective etching of some of the remaining portions of the second layers 106 of the stack 100 is then carried out. At least one gate dielectric and at least one gate conductor material are then deposited in second spaces formed by the previous selective etching of the remaining portions of the second layers 106, forming a gate 128 above and below, or around, each of the remaining portions of the first layers 104 of the stack 100.

The structure obtained at the end of the method is shown in FIG. 12. Other steps (not described here), such as producing source and drain regions, electrical contacts, etc., are carried out to complete the production of the microelectronic devices with 3D architecture 200 corresponding to MOS GAA transistors.

As an alternative to the fourth embodiment described above, it is possible that each second layer 106 is arranged between two first layers 104 and is in contact with these two first layers 104. In this case, after the first dielectric material 126 has been deposited, selective etching of some of the remaining portions of the first layers 104 of the stack 100 is carried out. At least one gate dielectric and at least one gate conductor material are then deposited in the second spaces formed by the previous selective etching of the remaining portions of the first layers 104, forming a gate 128 above and below, or around, each of the remaining portions of the second layers 106 of the stack 100.

1. A stack of layers suitable for producing a microelectronic device with 3D architecture comprising transistors, said stack including plural first layers of unintentionally doped silicon, plural second layers of unintentionally doped SiGe, and at least one third layer of P-doped silicon or of P-doped SiGe, such that said first layers, said second layers and said at least one third layers are stacked one above the other, said at least one third layer having a so-called “lower” side arranged on and in contact with a given semiconductor layer among said first layers or second layers or being arranged on and in contact with a semiconductor layer of a substrate, said at least one third layer having a so-called “upper” side opposite said lower side, said upper side being arranged below and in contact with another semiconductor layer among said first layers or second layers.

2. The stack according to claim 1, said stack being entirely made up of three different semiconductor materials.

3. The stack according to claim 2, the stack being entirely made up of first layers of unintentionally doped silicon, second layers of unintentionally doped SiGe, and at least one third layer of P-doped silicon or P-doped SiGe.

4. The stack of layers according to claim 1, wherein the silicon or SiGe of the third layer has a concentration of P-type dopants greater than or equal to 5·10¹⁹ at/cm³.

5. The stack of layers according to claim 1, wherein the intrinsic SiGe has a germanium concentration greater than or equal to 10% and less than 50%.

6. The stack of layers according to claim 1, wherein the number of first layers or second layers is comprised between 4 and 300.

7. The stack of layers according to claim 1, wherein each of the first and second layers is arranged between two third layers and is in contact with these two third layers.

8. The stack of layers according to claim 1, further including plural other third layers of P-doped silicon or P-doped SiGe, and wherein each of the first and third layers is arranged between two of the second layers and is in contact with these two second layers.

9. The stack of layers according to claim 1, comprising at least:
a first sub-stack formed by alternating first layers and second layers and such that each first layer of the first sub-stack is arranged between two second layers of the first sub-stack or that each second layer of the first sub-stack is arranged between two first layers of the first sub-stack;
a second sub-stack formed by alternating first and second layers and such that each first layer of the second sub-stack is arranged between two second layers of the second sub-stack or that each second layer of the second sub-stack is arranged between two first layers of the second sub-stack;
and wherein the third layer is arranged between the first and second sub-stacks.

10. The stack of layers according to claim 9, further including plural other third layers of p-doped silicon or p-doped SiGe between which the first and second sub-stacks are arranged.

11. The stack of layers according to claim 1, wherein the first and second layers are arranged one above the other in alternating rows, and the third layer is arranged under an assembly formed by the first and second layers.

12. A method for producing microelectronic devices with 3D architecture comprising transistors, including the implementation of the following steps:
a) producing a stack according to claim 7 on a substrate;
b) etching trenches or cavities through at least part of the thickness of the stack, such that remaining portions of the first, second and third layers form nanowires or nanosheets;
c) selectively etching some of the remaining portions of the first layers such that remaining parts of the first layers are designed to form transistor channels;
d) depositing at least one first dielectric material in first spaces formed by selectively etching some of the remaining portions of the first layers, next to the transistor channels;
e) selectively etching at least some of the remaining portions of the second layers;
d) depositing at least one second dielectric material in second spaces formed by selectively etching at least some of the remaining portions of the second layers, between the remaining portions of the third layers;
g) selectively etching remaining portions of the third layers;
h) depositing at least one gate dielectric and at least one gate conductor material in third spaces formed by selectively etching remaining portions of the third layers, forming a gate at least above and below each of the transistor channels.

13. A method for producing microelectronic devices with 3D architecture comprising transistors, including the implementation of the following steps:
a) producing a stack according to claim 7 on a substrate;
b) etching trenches or cavities through at least part of the thickness of the stack, such that remaining portions of the first, second and third layers form nanowires or nanosheets;
c) selectively etching some of the remaining portions of the second layers such that remaining parts of the second layers are designed to form transistor channels;
d) depositing at least one first dielectric material in first spaces formed by selectively etching some of the remaining portions of the first layers, next to the transistor channels;
e) selectively etching at least some of the remaining portions of the first layers;
d) depositing at least one second dielectric material in second spaces formed by selectively etching at least some of the remaining portions of the first layers, between the remaining portions of the third layers;
g) selectively etching remaining portions of the third layers;
h) depositing at least one gate dielectric and at least one gate conductor material in third spaces formed by selectively etching remaining portions of the third layers, forming a gate at least above and below each of the transistor channels.

14. A method for producing microelectronic devices with 3D architecture comprising transistors, including the implementation of the following steps:
a) producing a stack according to claim 8 on a substrate;
b) etching trenches or cavities through at least part of the thickness of the stack, such that remaining portions of the first, second and third layers form nanowires or nanosheets;
c) selectively etching some of the remaining portions of the first layers such that remaining parts of the first layers are designed to form transistor channels;
d) depositing at least one first dielectric material in first spaces formed by selectively etching some of the remaining portions of the first layers, next to the transistor channels;
e) selectively etching at least some of the remaining portions of the third layers;
d) depositing at least one second dielectric material in second spaces formed by selectively etching at least some of the remaining portions of the third layers, between the remaining portions of the second layers;
g) selectively etching remaining portions of the second layers;
h) depositing at least one gate dielectric and at least one gate conductor material in third spaces formed by selectively etching remaining portions of the second layers, forming a gate at least above and below each of the transistor channels.

15. The method according to claim 12, wherein steps e) and f) are implemented between steps b) and c).

16. A Method for producing microelectronic devices with 3D architecture comprising transistors, including the implementation of the following steps:
a) producing a stack according to claim 11 on a substrate;
b) etching trenches or cavities through at least part of the thickness of the stack, such that remaining portions of the first and second layers of the first and second sub-stacks and remaining portions of the third layer or third layers form nanowires or nanosheets;
e) selectively etching at least some of the remaining portions of the third layer or third layers;
d) depositing at least one first dielectric material in first spaces formed by selectively etching at least some of the remaining portions of the third layer or third layers;
e) selectively etching at least some of the remaining portions of the second layers of the first sub-stack when, in the first sub-stack, each first layer is arranged between two second layers, or selectively etching at least some of the remaining portions of the first layers of the first sub-stack when, in the first sub-stack, each second layer is arranged between two first layers;
h) depositing at least one gate dielectric and at least one gate conductor material in second spaces formed by the selective etching in step e), forming a gate at least above and below each of the remaining portions of the first or second layers of the first sub-stack.

17. The method according to claim 16, wherein:
when each first layer is arranged between two second layers in the first and second sub-stacks, step e) also includes selectively etching at least some of the remaining portions of the second layers of the second sub-stack, and step f) also includes depositing the gate dielectric and the gate conductor material in third spaces formed by selectively etching at least some of the remaining portions of the second layers of the second sub-stack, forming a gate at least above and below each of the remaining portions of the first layers of the second sub-stack, or
when each second layer is arranged between two first layers in the first and second sub-stacks, step e) also includes selectively etching at least some of the remaining portions of the first layers of the second sub-stack, and step f) also includes depositing the gate dielectric and the gate conductor material in third spaces formed by selectively etching at least some of the remaining portions of the first layers of the second sub-stack, forming a gate at least above and below each of the remaining portions of the second layers of the second sub-stack, or
when each first layer is arranged between two second layers in the first sub-stack and each second layer is arranged between two first layers in the second sub-stack, the method further includes, after step f): a step g) of selectively etching at least some of the remaining portions of the first layers of the second sub-stack, then a step h) of depositing at least one gate dielectric and at least one gate conductor material in third spaces formed by selectively etching at least some of the remaining portions of the first layers of the second sub-stack, forming a gate at least above and below each of the remaining portions of the second layers of the first sub-stack, or
when each second layer is arranged between two first layers in the first sub-stack and each first layer is arranged between two second layers in the second sub-stack, the method also includes, after step f), a step g) of selectively etching at least some of the remaining portions of the second layers of the second sub-stack, then a step h) of depositing at least one gate dielectric and at least one gate conductor material in third spaces formed by selectively etching at least some of the remaining portions of the second layers of the second sub-stack, forming a gate at least above and below each of the remaining portions of the first layers of the first sub-stack.

18. A method for producing microelectronic devices with 3D architecture comprising transistors, including the implementation of the following steps:
a) producing a stack according to claim 11 on a substrate;
b) etching trenches or cavities through at least part of the thickness of the stack, such that remaining portions of the first and second layers of the first and second sub-stacks and remaining portions of the third layer form nanowires or nanosheets;
e) selectively etching at least some of the remaining portions of the third layer;
d) depositing at least one first dielectric material in first spaces formed under the remaining portions of the first and second layers, providing electrical insulation between the remaining portions of the first and second layers and the substrate;
e) selectively etching at least some of the remaining portions of the first layers or second layers;
h) depositing at least one gate dielectric and at least one gate conductor material in second spaces formed by etching at least some of the remaining portions of the first layers or second layers, forming a gate at least above and below each of the remaining portions of the first layers or second layers.

19. The method according to claim 13, wherein steps e) and f) are implemented between steps b) and c).

20. A Method for producing microelectronic devices with 3D architecture comprising transistors, including the implementation of the following steps:
a) producing a stack according to claim 12 on a substrate;
b) etching trenches or cavities through at least part of the thickness of the stack, such that remaining portions of the first and second layers of the first and second sub-stacks and remaining portions of the third layer or third layers form nanowires or nanosheets;
e) selectively etching at least some of the remaining portions of the third layer or third layers;
d) depositing at least one first dielectric material in first spaces formed by selectively etching at least some of the remaining portions of the third layer or third layers;
e) selectively etching at least some of the remaining portions of the second layers of the first sub-stack when, in the first sub-stack, each first layer is arranged between two second layers, or selectively etching at least some of the remaining portions of the first layers of the first sub-stack when, in the first sub-stack, each second layer is arranged between two first layers;
h) depositing at least one gate dielectric and at least one gate conductor material in second spaces formed by the selective etching in step e), forming a gate at least above and below each of the remaining portions of the first or second layers of the first sub-stack.
